(19) United States
(12) Patent Application Publication
(10) Pub. No.: US 2025/0096114 A1
(43) Pub. Date: Mar. 20, 2025

(54) VIA STRUCTURE WITH IMPROVED SUBSTRATE GROUNDING

(71) Applicant: Intel Corporation, Santa Clara, CA (US)

(72) Inventors: Robin Chao, Portland, OR (US); Chiao-Ti Huang, Portland, OR (US); Guowei Xu, Portland, OR (US); Ting-Hsiang Hung, Beaverton, OR (US); Tao Chu, Portland, OR (US); Feng Zhang, Hillboro, OR (US); Chia-Ching Lin, Portland, OR (US); Yang Zhang, Rio Rancho, NM (US); Anand Murthy, Portland, OR (US); Conor P. Puls, Portland, OR (US)

(73) Assignee: Intel Corporation, Santa Clara, CA (US)

(21) Appl. No.: 18/469,810

(22) Filed: Sep. 19, 2023

(51) Int. Cl. H01L 23/522; H01L 23/528

(52) U.S. Cl. CPC H01L 23/5226; H01L 23/5283

(57) ABSTRACT

Techniques to form semiconductor devices can include one or more via structures having substrate taps. A semiconductor device includes a gate structure around or otherwise on a semiconductor region (or channel region). The gate structure may extend over the semiconductor regions of any number of devices along a given direction. The gate structure may be interrupted, for example, between two transistors with a via structure that extends through an entire thickness of the gate structure and includes a conductive core. The via structure has a conductive foot portion beneath the gate structure and a conductive arm portion extending from the conductive foot portion along a height of the gate structure. The conductive foot portion has a greater width along the given direction than any part of the conductive arm portion. The via structure may further include one or more dielectric layers between the conductive arm portion and the gate structure.

### BACKGROUND

As integrated circuits continue to scale downward in size, a number of challenges arise. For instance, reducing the size of memory and logic cells is becoming increasingly more difficult, as is reducing device spacing at the device layer. As transistors are packed more densely, the formation of certain device structures, such as via structure, becomes more challenging. Accordingly, there remain a number of non-trivial challenges with respect to forming semiconductor devices.

### BRIEF DESCRIPTION OF THE DRAWINGS

FIGS. 1A and 1B are cross-sectional and plan views, respectively, of some semiconductor devices that illustrate a via structure with a substrate tap, in accordance with an embodiment of the present disclosure.

FIGS. 2A-2N are cross-sectional views that illustrate various stages in an example process for forming semiconductor devices that have a via structure with a substrate tap, in accordance with some embodiments of the present disclosure.

FIG. 3 illustrates a cross-sectional view of a chip package containing one or more semiconductor dies, in accordance with some embodiments of the present disclosure.

FIG. 4 is a flowchart of a fabrication process for semiconductor devices having a via structure with a substrate tap, in accordance with an embodiment of the present disclosure.

FIG. 5 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form semiconductor devices that include one or more via structures having substrate taps. A given tap can be used, for instance, to reduce substrate charging during metal deposition, or to facilitate testing during quality testing, or to route a signal during circuit operation. The techniques can be used in any number of integrated circuit applications and are particularly useful with respect to device layer transistors, such as finFETs or gate-all-around transistors (e.g., ribbonFETs and nanowire FETs). In an example, a semiconductor device includes a gate structure around or otherwise on a semiconductor region. The semiconductor region can be, for example, a fin of semiconductor material that extends from a source region to a drain region along a first direction, or one or more nanowires or nanoribbons or nanosheets of semiconductor material that extend from a source region to a drain region along the first direction. The gate structure may extend over the semiconductor regions of any number of devices along a second direction substantially orthogonal to the first direction. The gate structure may be interrupted, for example, between two transistors with a via structure that extends through an entire thickness of the gate structure (e.g., along a third direction) and includes a conductive core to provide power or signal routing to backside interconnects. The via structure has a conductive foot portion beneath the gate structure and a conductive arm portion extending from the conductive foot portion along a height of the gate structure. The conductive foot portion has a greater width along the second direction than any part of the conductive arm portion. The conductive foot portion is provided during fabrication of the via structure to provide an enhanced grounding contact with the substrate while still allowing self-alignment of the conductive core within the via structure. Numerous variations and embodiments will be apparent in light of this disclosure.

### General Overview

As previously noted above, there remain a number of non-trivial challenges with respect to integrated circuit fabrication. In more detail, as devices become smaller and more densely packed, many structures become more challenging to fabricate as critical dimensions (CD) of the structures push the limits of current fabrication technology. Example structures like vias that pass through the device layer may be used in integrated circuit design for power and signal routing to backside connections. Since the via structures include a conductive core and must pass through conductive gate structures in the device layer, the via structure may include one or more dielectric layers between the conductive core and the conductive gate structure. Aligning the conductive core through the middle of the via structure can be challenging and self-aligning techniques have difficulties of their own. For example, self-aligning techniques yield a relatively small connection between the bottom of the conductive core and the substrate when depositing the metal. This leads to charge build-up within the substrate, which can cause problems when trying to deposit the metal materials of the conductive core.

Thus, and in accordance with an embodiment of the present disclosure, techniques are provided herein to form via structures that pass through the device layer (e.g., pass through a transistor gate structure) that have a lower substrate tap to improve substrate grounding during the via fabrication process. The transistors include semiconductor regions (e.g., fins, nanoribbons, nanosheets, or nanowires, or other channel regions) that extend in a first direction between a first source or drain region and a second source or drain region and the gate structure extends over the semiconductor regions along a second direction substantially orthogonal to the first direction.

The conductive core of the via structure may include a foot portion and an arm portion extending from the foot portion. The foot portion may act as a substrate tap to provide a wider landing on the substrate and decrease charge build-up within the substrate during the various metal deposition processes. The arm portion extends from the foot portion and through the height of the adjacent gate structure. Thus, according to some embodiments, the foot portion is below a bottom surface of the gate structure while the arm portion extends upwards from the foot portion and through the entire height of the gate structure. Additionally, the foot portion may have a width along the second direction that is greater than a width along the second direction of any part of the arm portion. One or more dielectric layers make up a dielectric structure between the arm portion of the conductive core and the gate structure. In this manner, the via structure may also act as a gate cut structure. According to some embodiments, the foot portion of the conductive core is below the dielectric structure, while the dielectric structure is arranged on sidewalls of the arm portion of the conductive core.

According to an embodiment, an integrated circuit includes a semiconductor device having a semiconductor region extending in a first direction from a source or drain region and a gate structure extending in a second direction over the semiconductor region, a dielectric layer beneath the gate structure, and a via structure spaced from the semiconductor region in the second direction and extending in a third direction along an entire thickness of the gate structure and along an entire thickness of the dielectric layer. The via structure includes a conductive foot portion and a conductive arm portion extending from the conductive foot portion. The conductive foot portion is below a bottom surface of the gate structure, and the conductive foot portion has a greater width in the second direction than a width in the second direction of any part of the conductive arm portion. The via structure may have any number of functions or purposes, such as providing a path for electrostatic discharge and/or power or signal routing. In some cases, the via structure may also act as a gate cut structure.

According to an embodiment, an electronic device includes a chip package having one or more dies. At least one of the one or more dies includes a semiconductor region extending in a first direction from a first source or drain region to a second source or drain region, a gate structure extending in a second direction over the semiconductor region, a dielectric layer beneath the gate structure, and a conductive via spaced from the semiconductor region in the second direction and extending in a third direction along an entire thickness of the gate structure and along an entire thickness of the dielectric layer. The conductive via includes a foot portion and an arm portion extending from the foot portion. The foot portion is below a bottom surface of the gate structure, and the foot portion has a greater width in the second direction than a width in the second direction of any part of the arm portion. The conductive via may have any number of functions or purposes, such as providing a path for electrostatic discharge and/or power or signal routing. In some cases, the conductive via may be surround by one or more layers of dielectric material, so as to also act as a gate cut structure.

According to an embodiment, an integrated circuit includes a semiconductor device having a semiconductor region extending in a first direction from a source or drain region and a gate structure extending in a second direction over the semiconductor region, a dielectric layer beneath the gate structure, and a via structure spaced from the semiconductor region in the second direction and extending in a third direction along an entire thickness of the gate structure and along an entire thickness of the dielectric layer. The via structure includes a conductive structure passing through an axial center of the via structure and a dielectric structure along sidewalls of the conductive structure. The dielectric structure is between a portion of the conductive structure and the gate structure, so as to effectively provide a gate cut. The conductive structure extends below a bottom surface of the dielectric structure. The bottom surface of the dielectric structure is beneath a top surface of the dielectric layer.

According to another embodiment, a method of forming an integrated circuit includes forming a fin comprising semiconductor material, the fin extending above a substrate and extending in a first direction; forming a dielectric layer adjacent to a subfin portion of the fin; forming source or drain regions at opposite ends of the fin; forming a gate structure on the dielectric layer and over the semiconductor material and extending in a second direction; forming a recess through an entire thickness of the gate structure and through an entire thickness of the dielectric layer; forming a sacrificial material within the recess such that a top surface of the sacrificial material is below a top surface of the dielectric layer; forming one or more dielectric layers along sidewalls of the recess and on a top surface of the sacrificial material; removing a portion of the one or more dielectric layers on the top surface of the sacrificial material; removing the sacrificial material from beneath the one or more dielectric layers to form a cavity beneath the one or more dielectric layers; forming one or more conductive materials on the one or more dielectric layers within the recess and within the cavity; and removing the substrate from the backside of the integrated circuit, wherein the removing exposes a bottom surface of the one or more conductive materials within the cavity.

The techniques can be used with any type of non-planar transistors, including finFETs (sometimes called tri-gate transistors), nanowire and nanoribbon transistors (sometimes called gate-all-around transistors), or forksheet transistors, to name a few examples. The source and drain regions can be, for example, epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a replacement metal gate, or RMG, process). Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the presence of a remaining portion of the conductive foot portion at the bottom of a via structure. The conductive foot portion will have a greater width compared to any part of the arm portion extending upwards from the foot portion. The dielectric structure along the edges of the via structure may also be observable, with the dielectric structure extending below a bottom surface of the gate structure and at least to the top of the foot portion.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the materials has an element that is not in the other material.

### Architecture

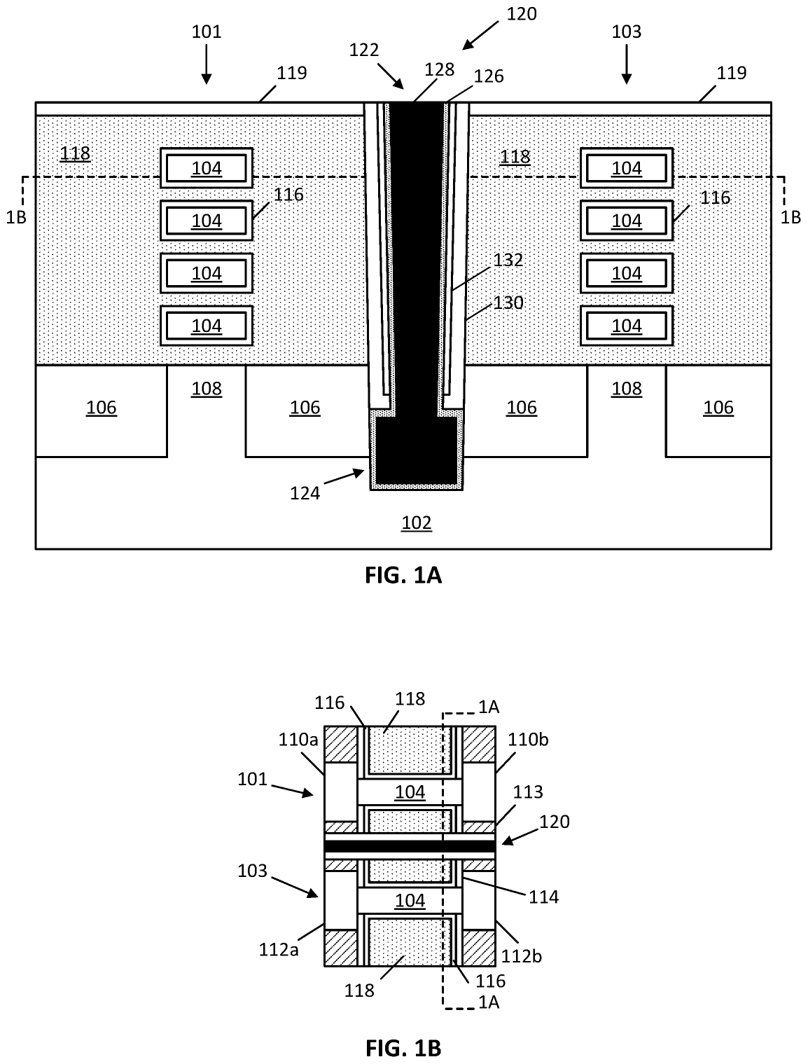

FIG. 1A is a cross-sectional view taken across two example semiconductor devices 101 and 103, according to an embodiment of the present disclosure. FIG. 1B is a top-down cross-section view of the adjacent semiconductor devices 101 and 103 taken across the dashed line 1B-1B depicted in FIG. 1A, and FIG. 1A illustrates the cross-section taken across the dashed line 1A-1A depicted in FIG. 1B. It should be noted that some of the material layers (such as dielectric cap 119) are not visible in the top-down view of FIG. 1B, given the location of the depicted cross-section. Each of semiconductor devices 101 and 103 may be non-planar metal oxide semiconductor (MOS) transistors, such as tri-gate (e.g., finFET) or gate-all-around (GAA) transistors, although other transistor topologies and types could also benefit from the gate cut techniques and structures provided herein. The illustrated example embodiments herein use the GAA structure. Semiconductor devices 101 and 103 represent a portion of an integrated circuit that may contain any number of similar semiconductor devices.

As can be seen, semiconductor devices 101 and 103 are formed on a substrate 102. Any number of semiconductor devices can be formed on substrate 102, but two are used here as an example. Substrate 102 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, substrate 102 can be a semiconductor-on-insulator substrate having a desired semiconductor layer over a buried insulator layer (e.g., silicon over silicon dioxide). Alternatively, substrate 102 can be a multilayer substrate or superlattice suitable for forming nanowires or nanoribbons (e.g., alternating layers of silicon and SiGe, or alternating layers indium gallium arsenide and indium phosphide). Any number of substrates can be used. In some example embodiments, a lower portion of (or all of) substrate 102 is removed and replaced with one or more backside interconnect layers to form backside signal and power routing.

Each of semiconductor devices 101 and 103 includes one or more nanoribbons 104 that extend parallel to one another along a direction between a source region and a drain region (e.g., a first direction into and out of the page in the cross-section view of FIG. 1A). Nanoribbons 104 are one example of semiconductor regions or semiconductor bodies that extend between source and drain regions. The term nanoribbon may also encompass other similar shapes such as nanowires or nanosheets. The semiconductor material of nanoribbons 104 may be formed from substrate 102. In some embodiments, semiconductor devices 101 and 103 may each include semiconductor regions in the shape of fins that can be, for example, native to substrate 102 (formed from the substrate itself), such as silicon fins etched from a bulk silicon substrate. Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, non-native fins can be formed in a so-called aspect ratio trapping based process, where native fins are etched away so as to leave fin-shaped trenches which can then be filled with an alternative semiconductor material (e.g., group IV or III-V material). In still other embodiments, the fins include alternating layers of material (e.g., alternating layers of silicon and SiGe) that facilitates forming of the illustrated nanoribbons 104 during a gate forming process where one type of the alternating layers is selectively etched away so as to liberate the other type of alternating layers within the channel region, so that a gate-all-around (GAA) process can then be carried out. Again, the alternating layers can be blanket deposited and then etched into fins or deposited into fin-shaped trenches, according to some examples.

As can further be seen, adjacent semiconductor devices are separated by a dielectric fill 106 that may include silicon dioxide. Dielectric fill 106 provides shallow trench isolation (STI) between any adjacent semiconductor devices, and adjacent subfin regions 108. Dielectric fill 106 can be any suitable dielectric material, such as silicon dioxide, aluminum oxide, or silicon oxycarbonitride.

Semiconductor devices 101 and 103 each include a subfin region 108, in this example. According to some embodiments, subfin region 108 comprises the same semiconductor material as substrate 102 and is adjacent to dielectric fill 106. According to some embodiments, nanoribbons 104 (or other semiconductor bodies) extend between a source and a drain region in the first direction to provide an active region for a transistor (e.g., the semiconductor region beneath the gate). The source and drain regions are not shown in the cross-section of FIG. 1A, but are seen in the top-down view of FIG. 1B where nanoribbons 104 of semiconductor device 101 extend between a first source or drain region 110a and a second source or drain region 110b (similarly, the nanoribbons 104 of semiconductor device 103 extend between a first source or drain region 112a and a second source or drain region 112b). FIG. 1B also illustrates spacer structures 114 that extend around the ends of nanoribbons 104 and along sidewalls of the gate structures between spacer structures 114. Spacer structures 114 may include a dielectric material, such as silicon nitride. Dielectric plugs 113 may be provided along the source/drain trenches in the second direction between adjacent source or drain regions. Dielectric plugs 113 may include any suitable dielectric material, such as silicon dioxide. Dielectric plugs 113 may be provided to substantially fill in a region between adjacent source or drain regions along a given source/drain trench.

According to some embodiments, the source and drain regions are epitaxial regions that are provided using an etch-and-replace process. In other embodiments one or both of the source and drain regions could be, for example, implantation-doped native portions of the semiconductor fins or substrate. Any semiconductor materials suitable for source and drain regions can be used (e.g., group IV and group III-V semiconductor materials). The source and drain regions may include multiple layers such as liners and capping layers to improve contact resistance. In any such cases, the composition and doping of the source and drain regions may be the same or different, depending on the polarity of the transistors. In an example, for instance, one transistor is a p-type MOS (PMOS) transistor, and the other transistor is an n-type MOS (NMOS) transistor. Any number of source and drain configurations and materials can be used.

According to some embodiments, gate structures extend over nanoribbons 104 of semiconductor devices 101 and 103 along a second direction across the page. The second direction may be substantially orthogonal to the first direction. Each gate structure includes a respective gate dielectric 116 and a gate electrode 118. Gate dielectric 116 represents any number of dielectric layers present between nanoribbons 104 and gate electrode 118. Gate dielectric 116 may also be present on the surfaces of other structures within the gate trench, such as on subfin region 108. Gate dielectric 116 may include any suitable gate dielectric material(s). In some embodiments, gate dielectric 116 includes a layer of native oxide material (e.g., silicon dioxide) on the nanoribbons or other semiconductor regions making up the channel region of the devices, and a layer of high-K dielectric material (e.g., hafnium oxide) on the native oxide.

Gate electrode 118 may represent any number of conductive layers, such as any metal, metal alloy, or doped polysilicon layers. In some embodiments, gate electrode 118 includes one or more workfunction metals around nanoribbons 104. In some embodiments, one of semiconductor devices 101 and 103 is a p-channel device that include a workfunction metal having titanium around its nanoribbons 104 and the other semiconductor device is an n-channel device that includes a workfunction metal having tungsten around its nanoribbons 104. Gate electrode 118 may also include a fill metal or other conductive material (e.g., tungsten, ruthenium, molybdenum, copper, aluminum) around the workfunction metals to provide the whole gate electrode structure. In some embodiments, a dielectric cap 119 may be formed over gate electrode 118 to protect the underlying material during processing. Dielectric cap 119 may be any suitable dielectric material, such as silicon nitride.

According to some embodiments, adjacent gate structures may be separated along the second direction (e.g., across the page) by a via structure 120. Via structure 120 extends vertically (e.g., in a third direction) through at least an entire thickness of the adjacent gate structure. In some embodiments, via structure 120 also extends through an entire thickness of dielectric fill 106. According to some embodiments, via structure 120 includes a conductive core made up of an arm portion 122 and a foot portion 124, and a dielectric structure on sidewalls of at least arm portion 122 of the conductive core. The dielectric structure may provide electrical isolation between the conductive core and gate electrode 118.

According to some embodiments, the conductive core may include a conductive liner 126 along edges of the conductive core and a conductive fill 128 on conductive liner 126 and within a remaining volume of the conductive core. Both conductive liner 126 and conductive fill 128 extend within arm portion 122 and foot portion 124 of the conductive core. In some examples, conductive liner 126 includes a material that enhances the adhesion of conductive fill 128. For example, conductive liner 126 may be titanium nitride. Conductive fill 128 may include any suitable conductive material, such as tungsten, ruthenium, molybdenum, or cobalt. Foot portion 124 may be arranged below a bottom surface of the gate structure (or a top surface of dielectric fill 106), while arm portion 122 extends away from foot portion 124 along an entire height of the gate structure. Due to natural tapering during fabrication, a width of the top of arm portion 122 along the second direction is wider than a width of the bottom of arm portion 122 along the second direction. The bottom of arm portion 122 directly couples with foot portion 124, according to some embodiments. A width of foot portion 124 along the second direction may be greater than a width in the second direction of any part of arm portion 122. Foot portion 124 creates a larger landing surface on substrate 102, thus reducing charging in substrate 102 during the metal deposition process.

According to some embodiments, the dielectric structure on the sidewalls of arm portion 122 include any number of dielectric layers. For example, a first dielectric layer 130 may be provided on a second dielectric layer 132. First dielectric layer 130 may be between second dielectric layer 132 and gate electrode 118. In some embodiments, second dielectric layer 132 is directly on arm portion 122 of the conductive core. According to some embodiments, first dielectric layer 130 has a higher dielectric constant compared to second dielectric layer 132. For example, first dielectric layer 130 can include a high-k dielectric material, such as silicon nitride or silicon carbide or any other material having a dielectric constant of at least 6.5, and second dielectric layer 132 includes a low-k dielectric layer, such as silicon dioxide or flowable oxide or any other material having a dielectric constant of at most 4.5.

According to some embodiments, foot portion 124 of the conductive core extends below the dielectric structure on the sidewalls of arm portion 122. Additionally, the bottom of the dielectric structure is below a bottom surface of the gate structure (or below a top surface of dielectric fill 106). According to some embodiments, an outer sidewall of the dielectric structure (e.g., outer sidewall of first dielectric layer 130) extends colinearly with an outer sidewall of foot portion 124.

Via structure 120 also extends in the first direction as seen in FIG. 1B such that it cuts across at least the entire width of the gate trench. According to some embodiments, via structure 120 may also extend further past spacer structures 114. In some examples, via structure 120 extends across more than one gate trench in the first direction (e.g., cutting through more than one gate structure running parallel along the second direction).

### Fabrication Methodology

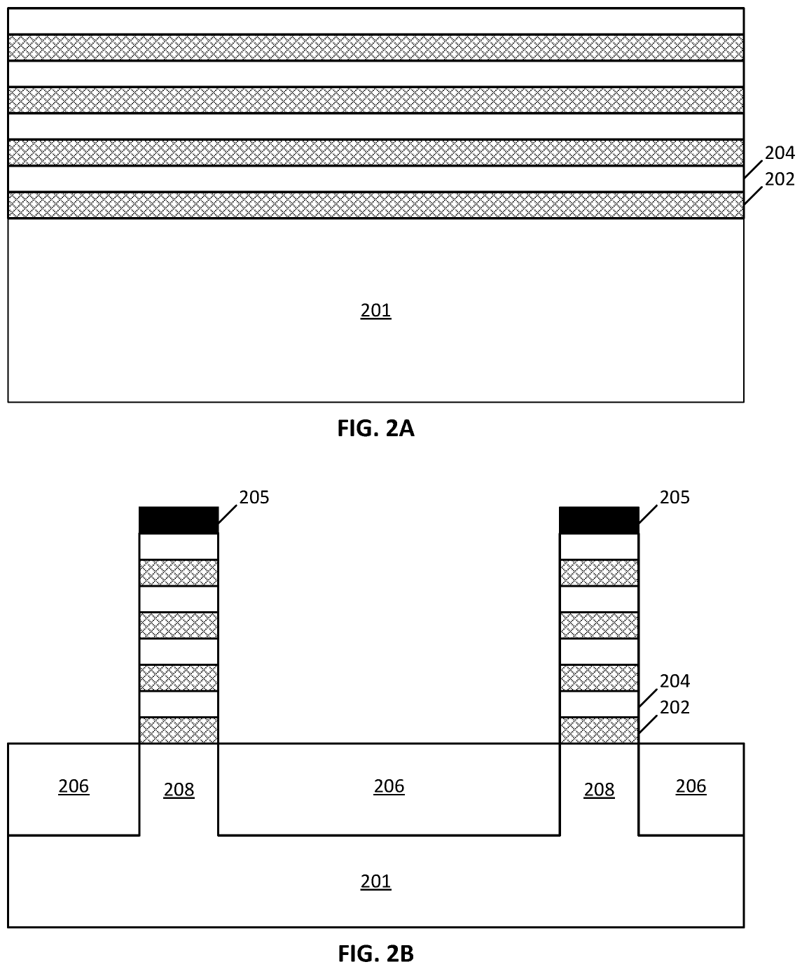

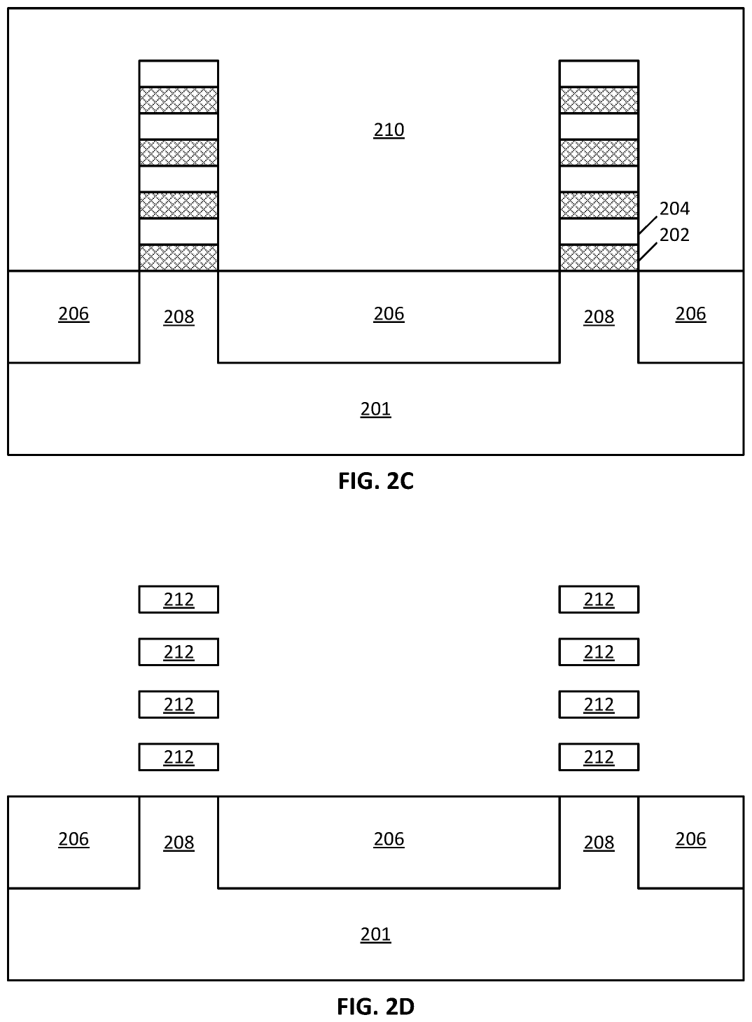

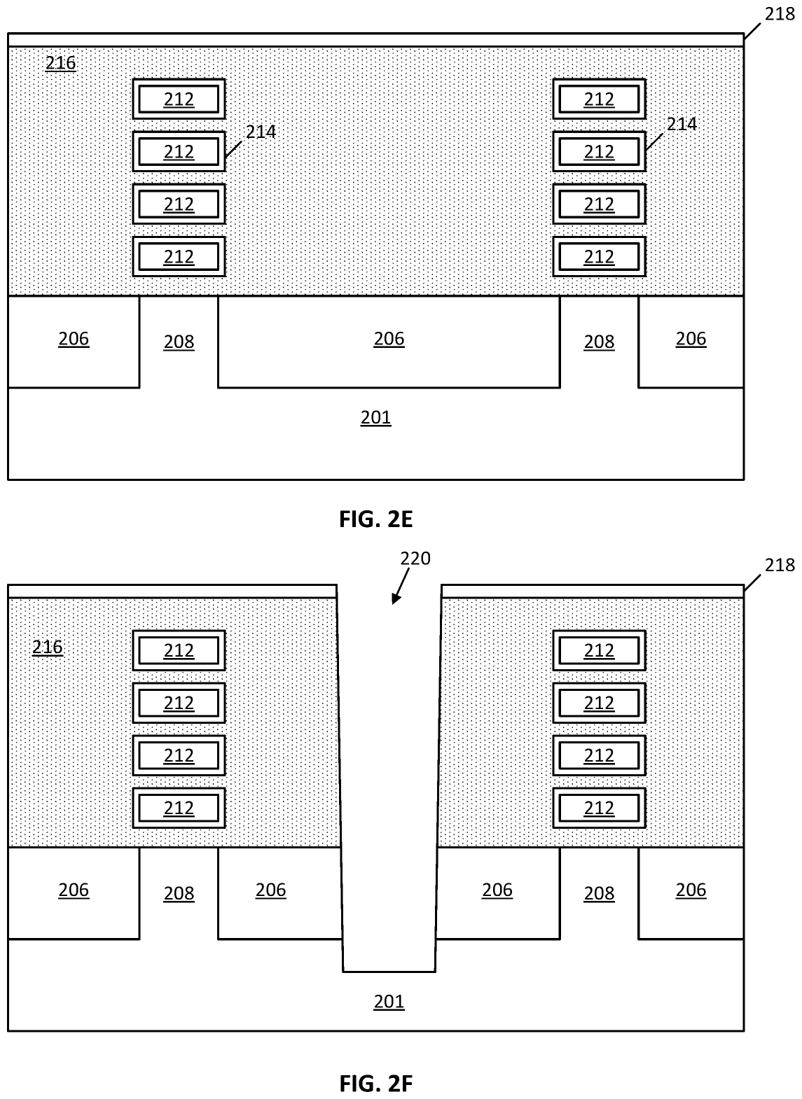

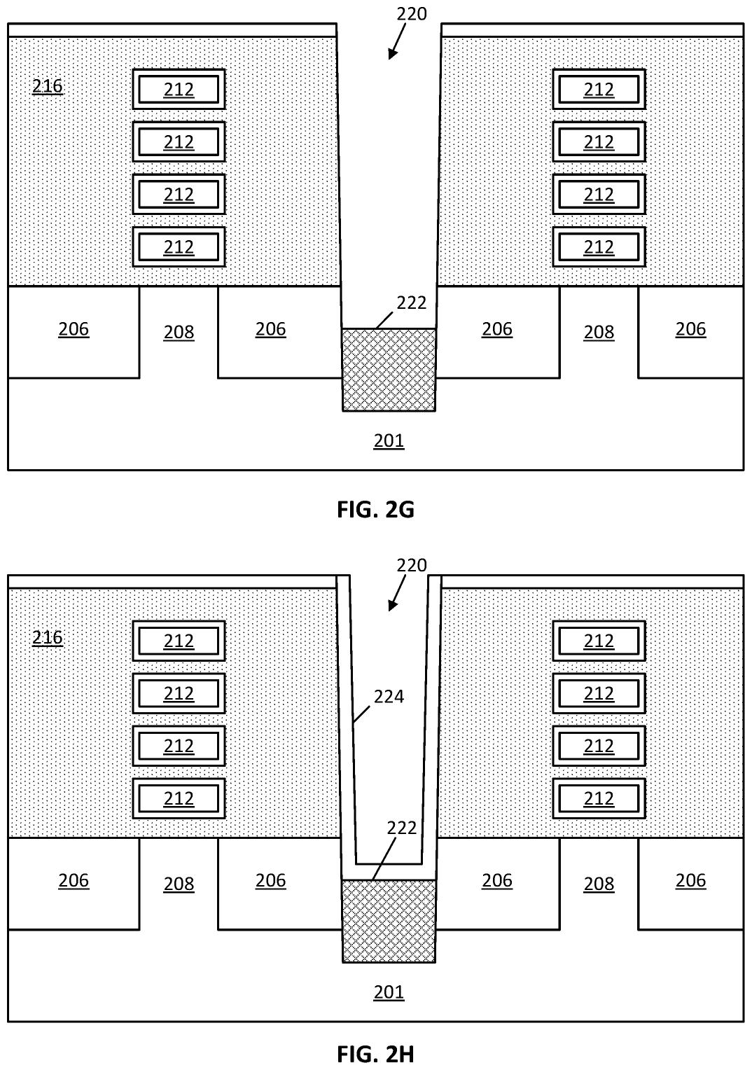

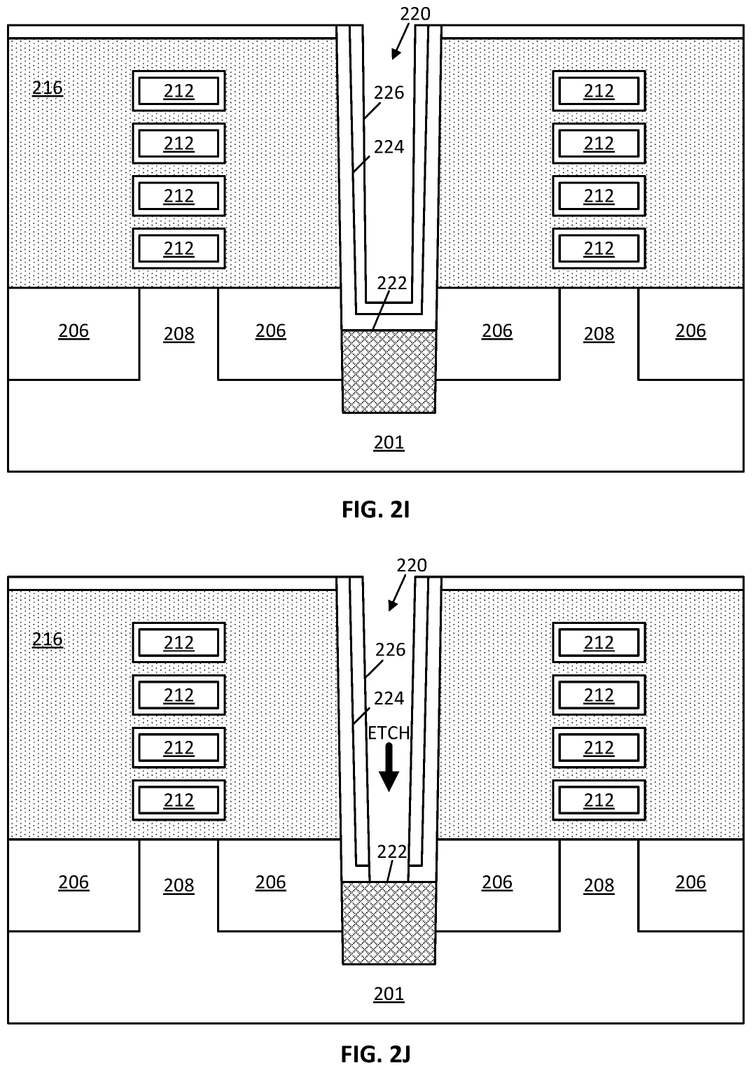

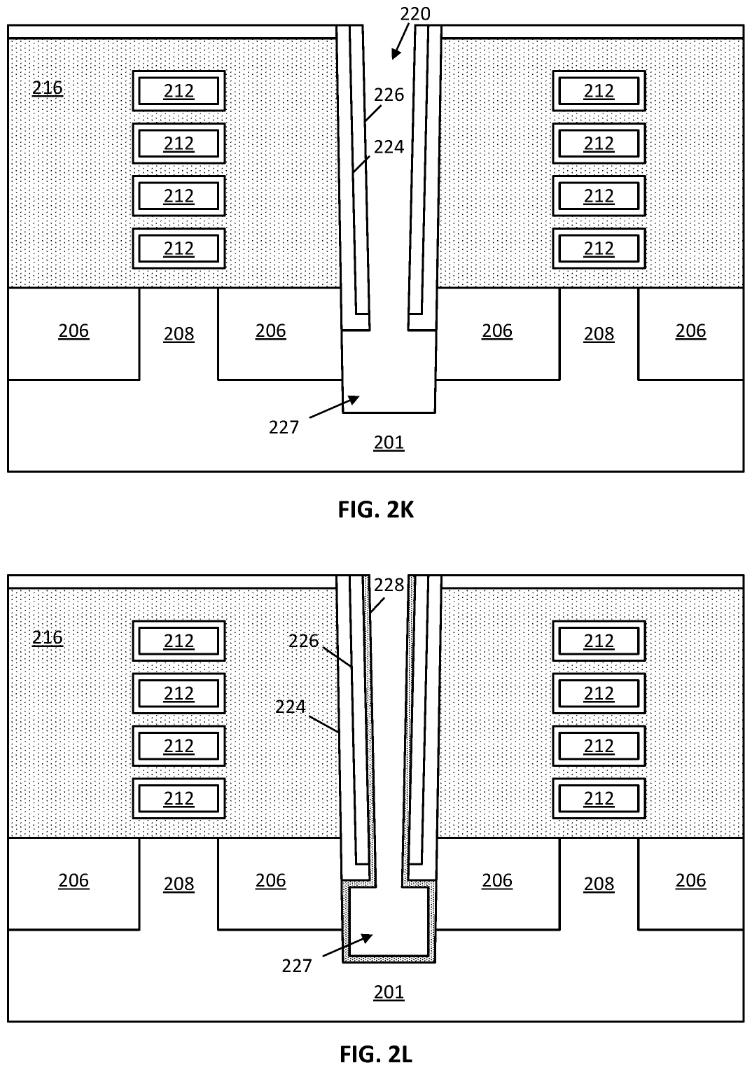

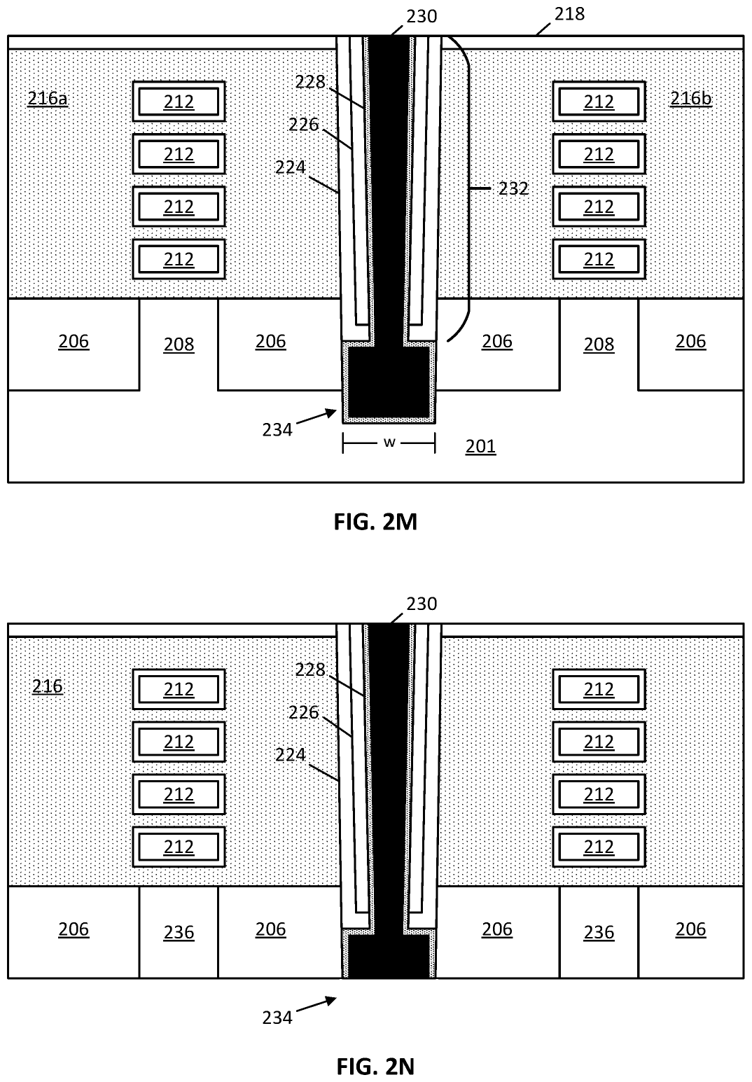

FIGS. 2A-2N include cross-sectional views that collectively illustrate an example process for forming an integrated circuit with semiconductor devices having at least one via structure with a substrate tap, in accordance with an embodiment of the present disclosure. Each figure shows an example structure that results from the process flow up to that point in time, so the depicted structure evolves as the process flow continues, culminating in the structure shown in FIG. 2N, which is similar to the structure shown in FIG. 1A. The illustrated integrated circuit structure may be part of a larger integrated circuit that includes other integrated circuitry not depicted. Example materials and process parameters are given, but the present disclosure is not intended to be limited to any specific such materials or parameters, as will be appreciated. Although the fabrication of a single via structure is illustrated in the aforementioned figures, it should be understood that any number of similar via structures can be fabricated across the integrated circuit using the same processes discussed herein.

FIG. 2A illustrates a cross-sectional view taken through a substrate 201 having a series of material layers formed over the substrate, according to an embodiment of the present disclosure. Alternating material layers may be deposited over substrate 201 including sacrificial layers 202 alternating with semiconductor layers 204. The alternating layers are used to form GAA transistor structures. Any number of alternating semiconductor layers 204 and sacrificial layers 202 may be deposited over substrate 201. The description above for substrate 102 applies equally to substrate 201.

According to some embodiments, sacrificial layers 202 have a different material composition than semiconductor layers 204. In some embodiments, sacrificial layers 202 are silicon germanium (SiGe) while semiconductor layers 204 include a semiconductor material suitable for use as a nanoribbon such as silicon (Si), SiGe, germanium, or III-V materials like indium phosphide (InP) or gallium arsenide (GaAs). In examples where SiGe is used in each of sacrificial layers 202 and in semiconductor layers 204, the germanium concentration is different between sacrificial layers 202 and semiconductor layers 204. For example, sacrificial layers 202 may include a higher germanium content compared to semiconductor layers 204. In some examples, semiconductor layers 204 may be doped with either n-type dopants (to produce a p-channel transistor) or p-type dopants (to produce an n-channel transistor).

While dimensions can vary from one example embodiment to the next, the thickness of each sacrificial layer 202 may be between about 5 nm and about 20 nm. In some embodiments, the thickness of each sacrificial layer 202 is substantially the same (e.g., within 1-2 nm). The thickness of each of semiconductor layers 204 may be about the same as the thickness of each sacrificial layer 202 (e.g., about 5-20 nm). Each of sacrificial layers 202 and semiconductor layers 204 may be deposited using any known or proprietary material deposition technique, such as chemical vapor deposition (CVD), plasma-enhanced chemical vapor deposition (PECVD), physical vapor deposition (PVD), or atomic layer deposition (ALD).

FIG. 2B depicts the cross-section view of the structure shown in FIG. 2A following the formation of a cap layer 205 and the subsequent formation of fins beneath cap layer 205, according to an embodiment. Cap layer 205 may be any suitable hard mask material such as a carbon hard mask (CHM) or silicon nitride. Cap layer 205 is patterned into rows to form corresponding rows of fins from the alternating layer stack of sacrificial layers 202 and semiconductor layers 204. The rows of fins extend lengthwise in a first direction (e.g., into and out of the page).

According to some embodiments, an anisotropic etching process through the layer stack continues into at least a portion of substrate 201. The etched portion of substrate 201 may be filled with a dielectric fill 206 that acts as shallow trench isolation (STI) between adjacent fins. Dielectric fill 206 may be any suitable dielectric material such as silicon dioxide. Subfin regions 208 represent remaining portions of substrate 201 between dielectric fill 206, according to some embodiments.

FIG. 2C depicts the cross-section view of the structure shown in FIG. 2B following the formation of a sacrificial gate 210 extending across the fins in a second direction different from the first direction, according to some embodiments. Sacrificial gate 210 may extend across the fins in a second direction that is orthogonal to the first direction. According to some embodiments, the sacrificial gate material is formed in parallel strips across the integrated circuit and removed in all areas not protected by a gate masking layer. Sacrificial gate 210 may be any suitable material that can be selectively removed without damaging the semiconductor material of the fins. In some examples, sacrificial gate 210 includes polysilicon. In some cases, sacrificial gate 210 may also include a gate dielectric, such as an oxide of the fin material.

Following the formation of sacrificial gate 210 (and prior to replacement of sacrificial gate 210 with a metal gate), additional semiconductor device structures are formed that are not shown in these cross-sections. These additional structures include spacer structures on the sidewalls of sacrificial gate 210 and source and drain regions on either ends of each of the fins. The formation of such structures can be accomplished using any number of processing techniques.

FIG. 2D depicts the cross-section view of the structure shown in FIG. 2C following the removal of sacrificial gate 210 and the removal of sacrificial layers 202, according to some embodiments. In examples where any gate masking layers are still present, they may also be removed at this time. Once sacrificial gate 210 is removed, the fins that had been beneath sacrificial gate 210 are exposed.

In the example where the fins include alternating semiconductor layers, sacrificial layers 202 are selectively removed to release nanoribbons 212 that extend between corresponding source or drain regions. Each vertical set of nanoribbons 212 represents the semiconductor or channel region of a different semiconductor device. It should be understood that nanoribbons 212 may also be nanowires or nanosheets (e.g., from a forksheet arrangement) or fins (e.g., for a finFET arrangement). Sacrificial gate 210 and sacrificial layers 202 may be removed using the same isotropic etching process or different isotropic etching processes.

FIG. 2E depicts the cross-section view of the structure shown in FIG. 2D following the formation of a gate structure and subsequent polishing, according to some embodiments. The gate structure includes a gate dielectric 214 and a conductive gate electrode 216. Gate dielectric 214 may be first formed around nanoribbons 212 prior to the formation of gate electrode 216. The gate dielectric 214 may include any suitable dielectric material (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, gate dielectric 214 includes a layer of hafnium oxide with a thickness between about 1 nm and about 5 nm. In some embodiments, gate dielectric 214 may include one or more silicates (e.g., titanium silicate, tungsten silicate, niobium silicate, and silicates of other transition metals). In some cases, gate dielectric 214 may include a first layer on nanoribbons 212, and a second layer on the first layer. The first layer can be, for instance, an oxide of the semiconductor material of nanoribbons 212 (e.g., silicon dioxide) and the second layer can be a high-k dielectric material (e.g., hafnium oxide). More generally, gate dielectric 214 can include any number of dielectric layers. According to some embodiments, gate dielectric 214 forms along all surfaces exposed within the gate trench, such as along inner sidewalls of the spacer structures and along the top surfaces of dielectric fill 206 and subfin regions 208.

As noted above, gate electrode 216 can represent any number of conductive layers. The conductive gate electrode 216 may be deposited using electroplating, electroless plating, CVD, PECVD, ALD, or PVD, to name a few examples. In some embodiments, gate electrode 216 includes doped polysilicon, a metal, or a metal alloy. Example suitable metals or metal alloys include aluminum, tungsten, cobalt, molybdenum, ruthenium, titanium, tantalum, copper, and carbides and nitrides thereof. Gate electrode 216 may include, for instance, a metal fill material along with one or more workfunction layers, resistance-reducing layers, and/or barrier layers. The workfunction layers can include, for example, p-type workfunction materials (e.g., titanium nitride) for PMOS gates, or n-type workfunction materials (e.g., titanium aluminum carbide) for NMOS gates. Following the formation of the gate structure, the entire structure may be polished or planarized such that the top surface of the gate structure (e.g., top surface of gate electrode 216) is planar with the top surface of other semiconductor elements, such as the spacer structures that define the gate trench.

According to some embodiments, gate electrode 216 may be recessed between the spacer structures and a dielectric cap 218 is formed within the recessed area. Dielectric cap 218 may include any suitable dielectric material, such as silicon nitride. In some examples, dielectric cap 218 includes the same dielectric material as the spacer structures.

FIG. 2F illustrates another cross-section view of the structure shown in FIG. 2E following the formation of a via recess 220 through at least an entire thickness of gate electrode 216, according to some embodiments. Via recess 220 may have a high height-to-width aspect ratio of 5:1 or more, such as between 6:1 and 10:1 and may be formed via a series of RIE and passivation steps to etch through the conductive material of gate electrode 216. Via recess 220 may be tapered and have a largest width along a top surface of gate electrode 216 (or a top surface of dielectric cap 218). In some examples, the largest width of via recess 220 is between about 30 nm and about 50 nm. In some embodiments, via recess 220 extends through an entire thickness of dielectric fill 206 and into the underlying substrate 201.

FIG. 2G illustrates another cross-section view of the structure shown in FIG. 2F following the formation of a sacrificial material 222 within via recess 220, according to some embodiments. Sacrificial material 222 may be any suitable material that can be easily removed at a later time without damaging surrounding dielectric materials. In some examples, sacrificial material 222 includes carbon hard mask (CHM). Sacrificial material 222 may first be deposited within via recess 220 and etched back to a final thickness such that a top surface of sacrificial material 222 is at least below a bottom surface of the gate structure (or below a top surface of dielectric fill 206). According to some embodiments, the top surface of sacrificial material 222 is also above a bottom surface of dielectric fill 206.

FIG. 2H illustrates another cross-section view of the structure shown in FIG. 2G following the formation of a first dielectric layer 224 within via recess 220, according to some embodiments. First dielectric layer 224 may include a high-k dielectric material. In some examples first dielectric layer 224 includes silicon nitride. First dielectric layer 224 may be conformally deposited along all surfaces within via recess 220, including on a top surface of sacrificial material 222, using any suitable conformal deposition technique, such as ALD. In some embodiments, first dielectric layer 224 is silicon nitride that is deposited using a relatively low temperature (e.g., less than 200° C.).

FIG. 2I illustrates another cross-section view of the structure shown in FIG. 2H following the formation of a second dielectric layer 226 on first dielectric layer 224 within via recess 220, according to some embodiments. Second dielectric layer 226 may include a low-k dielectric material. In some examples, second dielectric layer 226 includes silicon dioxide. Second dielectric layer 226 may be conformally deposited along all exposed surfaces of first dielectric layer 224 within via recess 220 using any suitable conformal deposition technique, such as ALD. The combination of first dielectric layer 224 and second dielectric layer 226 are part of a dielectric structure. According to some embodiments, the dielectric structure includes any number of other dielectric layers formed within via recess 220.

FIG. 2J illustrates another cross-section view of the structure shown in FIG. 2I following an etching process through the bottom portions of each of first dielectric layer 224 and second dielectric layer 226, according to some embodiments. Sometimes referred to as a “punch-through” etch, an anisotropic RIE process may be performed to remove dielectric materials exposed at the bottom of via recess 220. In some examples, the etching process also removes a portion of sacrificial material 222.

FIG. 2K illustrates another cross-section view of the structure shown in FIG. 2J following the removal of sacrificial material 222, according to some embodiments. An ashing process or any other suitable isotropic etching process may be used to remove sacrificial material 222. The removal of sacrificial material 222 forms a cavity 227 along the bottom of via recess 220 and beneath the dielectric structure.

FIG. 2L illustrates another cross-section view of the structure shown in FIG. 2K following the formation of a conductive liner 228 within via recess 220, according to some embodiments. Conductive liner 228 may include a conductive material that acts as an adhesion promotor for a later-deposited conductive material. In some examples, conductive liner 228 includes titanium nitride. Conductive liner 228 may be conformally deposited along all exposed surfaces within via recess 220 using any suitable conformal deposition technique, such as ALD. Accordingly, conductive liner 228 forms on the inner sidewalls of the dielectric structure and along all surfaces of cavity 227 beneath the dielectric structure. Conductive liner 228 may have a thickness between about 1 nm and about 4 nm.

FIG. 2M illustrates another cross-section view of the structure shown in FIG. 2L following the formation of a conductive fill 230 within a remaining volume of via recess 220, according to some embodiments. Conductive fill 230 may be formed on conductive liner 228 and together the conductive materials form the conductive core of the overall via structure. Conductive fill 230 may be any suitable conductive material, such as tungsten, ruthenium, molybdenum, or cobalt. The conductive material of conductive fill 230 may be deposited within via recess 220 and on a top surface of the integrated circuit structure, then polished back until a top surface of conductive fill 230 is substantially coplanar with a top surface of dielectric cap 218.

The conductive core (including any of the deposited conductive materials, such as conductive liner 228 and conductive fill 230) includes an arm portion 232 and a foot portion 234 beneath arm portion 232, according to some embodiments. Foot portion 234 acts as a substrate tap to provide a relatively wide connection to substrate 201 during the metal deposition process(es). According to some embodiments, foot portion 234 includes a widest width w that is greater than the width of any part of arm portion 232. In some examples, foot portion 234 has a widest width at its top surface (e.g., where it connects to arm portion 232) due to the natural taper of via recess 220. The widest width w of foot portion 234 may be between about 15 nm and about 30 nm. According to some embodiments, the dielectric structure is arranged on the sidewalls of arm portion 232 and foot portion 234 is below a bottom surface of the dielectric structure. The bottom surface of the dielectric structure (and similarly the top surface of foot portion 234) may be below a bottom surface of the gate structure or below a top surface of dielectric fill 206. Since the dielectric structure and foot portion 234 may be formed to the edge of via recess 220, an outer sidewall of the dielectric structures (e.g., outer sidewall of first dielectric layer 224) may be colinearly aligned with an outer sidewall of foot portion 234.

Since the conductive core is formed within a remaining volume of recess 220 following the conformal formation of the dielectric structure on the sidewalls of recess 220, the conductive core may be self-aligned along a central axis of the via structure. Thus, according to some embodiments, a first distance along the second direction between arm portion 232 and adjacent gate electrode 216a is substantially the same as a second distance along the second direction between arm portion 232 and adjacent gate electrode 216b, the first and second distances being on a same plane passing through arm portion 232.

FIG. 2N illustrates another cross-section view of the structure shown in FIG. 2M following the removal of semiconductor materials from the backside and replacement with dielectric materials, according to some embodiments. Once all front-side processes have been performed across the integrated circuit, substrate 201 may be removed via any arrangement of grinding, polishing, and/or chemical etching processes. According to some embodiments, all materials are removed from the backside up until at least a bottom surface of dielectric fill 206 is exposed, which may accordingly remove a bottom portion of foot portion 234. According to some embodiments, subfin regions 208 are also removed from the backside and replaced with dielectric material 236, which may include any number of dielectric layers. In some examples, dielectric material 236 may be the same or similar dielectric material as dielectric fill 206. In some examples, subfin regions 208 remain on the backside and another dielectric layer is formed over the backside surfaces of subfin regions 208. One or more backside conductive layers can be formed that contact the lower surface of foot portion 234.

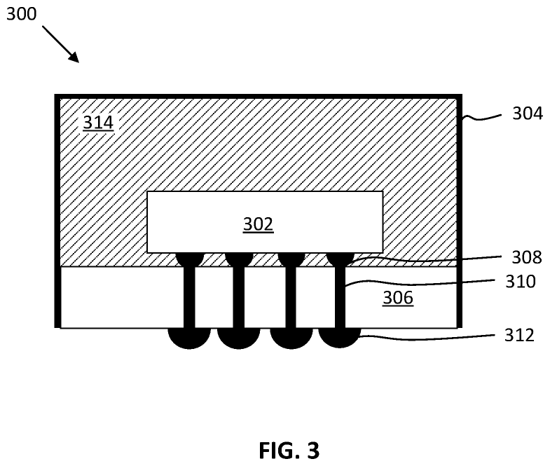

FIG. 3 illustrates an example embodiment of a chip package 300, in accordance with an embodiment of the present disclosure. As can be seen, chip package 300 includes one or more dies 302. One or more dies 302 may include at least one integrated circuit having semiconductor devices, such as any of the semiconductor devices disclosed herein. One or more dies 302 may include any other circuitry used to interface with other devices formed on the dies, or other devices connected to chip package 300, in some example configurations.

As can be further seen, chip package 300 includes a housing 304 that is bonded to a package substrate 306. The housing 304 may be any standard or proprietary housing, and may provide, for example, electromagnetic shielding and environmental protection for the components of chip package 300. The one or more dies 302 may be conductively coupled to a package substrate 306 using connections 308, which may be implemented with any number of standard or proprietary connection mechanisms, such as solder bumps, ball grid array (BGA), pins, or wire bonds, to name a few examples. Package substrate 306 may be any standard or proprietary package substrate, but in some cases includes a dielectric material having conductive pathways (e.g., including conductive vias and lines) extending through the dielectric material between the faces of package substrate 306, or between different locations on each face. In some embodiments, package substrate 306 may have a thickness less than 1 millimeter (e.g., between 0.1 millimeters and 0.5 millimeters), although any number of package geometries can be used. Additional conductive contacts 312 may be disposed at an opposite face of package substrate 306 for conductively contacting, for instance, a printed circuit board (PCB). One or more vias 310 extend through a thickness of package substrate 306 to provide conductive pathways between one or more of connections 308 to one or more of contacts 312. Vias 310 are illustrated as single straight columns through package substrate 306 for ease of illustration, although other configurations can be used (e.g., damascene, dual damascene, through-silicon via, or an interconnect structure that meanders through the thickness of substrate 306 to contact one or more intermediate locations therein). In still other embodiments, vias 310 are fabricated by multiple smaller stacked vias, or are staggered at different locations across package substrate 306. In the illustrated embodiment, contacts 312 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 312, to inhibit shorting.

In some embodiments, a mold material 314 may be disposed around the one or more dies 302 included within housing 304 (e.g., between dies 302 and package substrate 306 as an underfill material, as well as between dies 302 and housing 304 as an overfill material). Although the dimensions and qualities of the mold material 314 can vary from one embodiment to the next, in some embodiments, a thickness of mold material 314 is less than 1 millimeter. Example materials that may be used for mold material 314 include epoxy mold materials, as suitable. In some cases, the mold material 314 is thermally conductive, in addition to being electrically insulating.

### Methodology

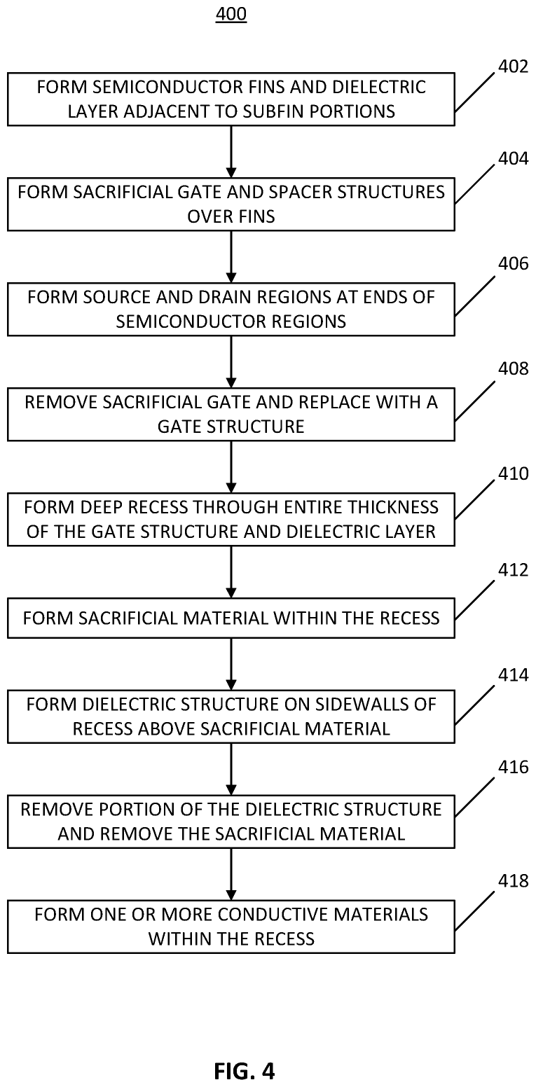

FIG. 4 is a flow chart of a method 400 for forming at least a portion of an integrated circuit, according to an embodiment. Various operations of method 400 may be illustrated in FIGS. 2A-2N. However, the correlation of the various operations of method 400 to the specific components illustrated in the aforementioned figures is not intended to imply any structural and/or use limitations. Rather, the aforementioned figures provide one example embodiment of method 400. Other operations may be performed before, during, or after any of the operations of method 400. For example, method 400 does not explicitly describe all processes that are performed to form common transistor structures. Some of the operations of method 400 may be performed in a different order than the illustrated order.

Method 400 begins with operation 402 where any number of parallel semiconductor fins are formed, according to some embodiments. The semiconductor material in the fins may be formed from a substrate such that the fins are an integral part of the substrate (e.g., etched from a bulk silicon substrate). Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, the fins include alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. The alternating layers can be blanket deposited and then etched into fins, or deposited into fin-shaped trenches. The fins may also include a cap structure over each fin that is used to define the locations of the fins during, for example, an RIE process. The cap structure may be a dielectric material, such as silicon nitride.

According to some embodiments, a dielectric layer is formed around subfin portions of the one or more fins. In some embodiments, the dielectric layer extends between each pair of adjacent parallel fins and runs lengthwise in the same direction as the fins. In some embodiments, the anisotropic etching process that forms the fins also etches into a portion of the substrate and the dielectric layer may be formed within the recessed portions of the substrate. Accordingly, the dielectric layer acts as shallow trench isolation (STI) between adjacent fins. The dielectric layer may be any suitable dielectric material, such as silicon dioxide.

Method 400 continues with operation 404 where a sacrificial gate and spacer structures are formed over the fins. The sacrificial gate may be patterned using a gate masking layer in a strip that runs orthogonally over the fins (many gate masking layers and corresponding sacrificial gates may be formed parallel to one another (e.g., forming a cross-hatch pattern with the fins). The gate masking layer may be any suitable hard mask material, such as CHM or silicon nitride. The sacrificial gate may be formed from any suitable material that can be selectively removed at a later time without damaging the semiconductor material of the fins. In one example, the sacrificial gate includes polysilicon. The spacer structures may be deposited and then etched back such that the spacer structures remain mostly only on sidewalls of any exposed structures. According to some embodiments, the spacer structures may be any suitable dielectric material, such as silicon nitride or silicon oxynitride.

Method 400 continues with operation 406 where source or drain regions are formed at the ends of the semiconductor regions of each of the fins. Any portions of the fins not protected by the sacrificial gate and spacer structures may be removed using, for example, an anisotropic etching process followed by the epitaxial growth of the source or drain regions from the exposed ends of the semiconductor layers in the fins. In some example embodiments, the source or drain regions are NMOS source or drain regions (e.g., epitaxial silicon) or PMOS source or drain regions (e.g., epitaxial SiGe). Another dielectric fill may be formed adjacent to the various source or drain regions for additional electrical isolation between adjacent regions. The dielectric fill may also extend over a top surface of the source or drain regions. In some embodiments, topside conductive contacts may be formed through the dielectric fill to contact one or more of the source or drain regions.

Method 400 continues with operation 408 where the sacrificial gate is removed and replaced with a gate structure. The sacrificial gate may be removed using an isotropic etching process that selectively removes all of the material from the sacrificial gate, thus exposing the various fins between the set of spacer structures. In the example case where GAA transistors are used, any sacrificial layers within the exposed fins between the spacer structures may also be removed to release nanoribbons, nanosheets, or nanowires of semiconductor material.

The gate structure may include both a gate dielectric and a gate electrode. The gate dielectric is first formed over the exposed semiconductor regions between the spacer structures followed by forming the gate electrode within the remainder of the trench between the spacer structures, according to some embodiments. The gate dielectric may include any number of dielectric layers deposited using a CVD process, such as ALD. The gate electrode can include any number of conductive material layers, such as any metals, metal alloys, or polysilicon. The gate electrode may be deposited using electroplating, electroless plating, CVD, ALD, PECVD, or PVD, to name a few examples. In some embodiments, the gate electrode may be recessed, and a dielectric gate cap is formed within the recessed area. The dielectric gate cap may have a thickness between 10 nm and 20 nm, such as around 15 nm.

Method 400 continues with operation 410 where a deep recess is formed through an entire thickness of the gate structure. A mask structure may be formed over the gate structure and an opening may be formed through the mask structure to expose a portion of the underlying gate electrode. According to some embodiments, the opening through the mask structure is at a location where the deep recess is to be formed through the underlying gate electrode. The mask structure may include any number of hard mask layers, such as any dielectric layers or carbon hard mask layers. The opening may be formed using a directional RIE process. According to some embodiments, the deep recess has a high height-to-width aspect ratio of at least 5:1 and extends through at least an entire thickness of the gate structure. In some examples, the deep recess also extends through an entire thickness of the dielectric layer between devices and into the underlying substrate.

Method 400 continues with operation 412 where a sacrificial material is formed within the recess. The sacrificial material may be any suitable material that can be easily removed at a later time without damaging surrounding dielectric materials. In some examples, the sacrificial material includes CHM. The sacrificial material may first be deposited both within and outside of the deep recess and etched back to a final thickness within the bottom of the recess. For example, a top surface of the sacrificial material may be at least below a bottom surface of the gate structure (or below a top surface of the dielectric layer). According to some embodiments, the top surface of the sacrificial material is also above a bottom surface of the dielectric layer.

Method 400 continues with operation 414 where a dielectric structure is formed on sidewalls of the deep recess above the sacrificial material. According to some embodiments, the dielectric structure also forms on the top surface of the sacrificial material within the deep recess. The dielectric structure may include any number of dielectric layers. For example, the dielectric structure may include a first dielectric layer on the sidewalls of the recess (and contacting the adjacent gate electrode) and a second dielectric layer on the first dielectric layer. Each of the first and second dielectric layers may be conformally deposited using, for example, ALD. In some embodiments, the first dielectric layer has a higher dielectric constant compared to the second dielectric layer. In one example, the first dielectric layer includes silicon nitride and the second dielectric layer includes silicon dioxide. The silicon nitride of the first dielectric layer may be deposited at a relatively low temperature of less than around 200° C. The low temperature deposition may help to reduce the dielectric constant of the first dielectric layer.

Method 400 continues with operation 416 where a lower portion of the dielectric structure is removed and the sacrificial material is removed. An anisotropic RIE process (e.g., a punch-through etch) may be performed to remove any dielectric materials exposed at the bottom of the deep recess. In some examples, the etching process also removes a portion of the sacrificial material. The bottom portion of the dielectric structure may be etched away at least until a top surface of the sacrificial material is exposed. An ashing process or any other suitable isotropic etching process may be used to then remove the sacrificial material. The removal of the sacrificial material forms a cavity along the bottom of the deep recess and beneath the dielectric structure.

Method 400 continues with operation 418 where one or more conductive materials are formed within a remaining volume of the recess. According to some embodiments, the one or more conductive materials collectively create a conductive core of the via structure. The conductive core includes a foot portion within the cavity and an arm portion extending away from the cavity and along a full height of the gate structure. The conductive core may include a conductive liner and a conductive fill on the conductive liner. The conductive liner may include titanium nitride and the conductive fill may include any of tungsten, ruthenium, molybdenum, or cobalt. Since the conductive core is formed within a remaining volume of the deep recess following the conformal formation of the dielectric structure on the sidewalls of the deep recess, the conductive core is self-aligned along a central axis of the via structure.

### Example System

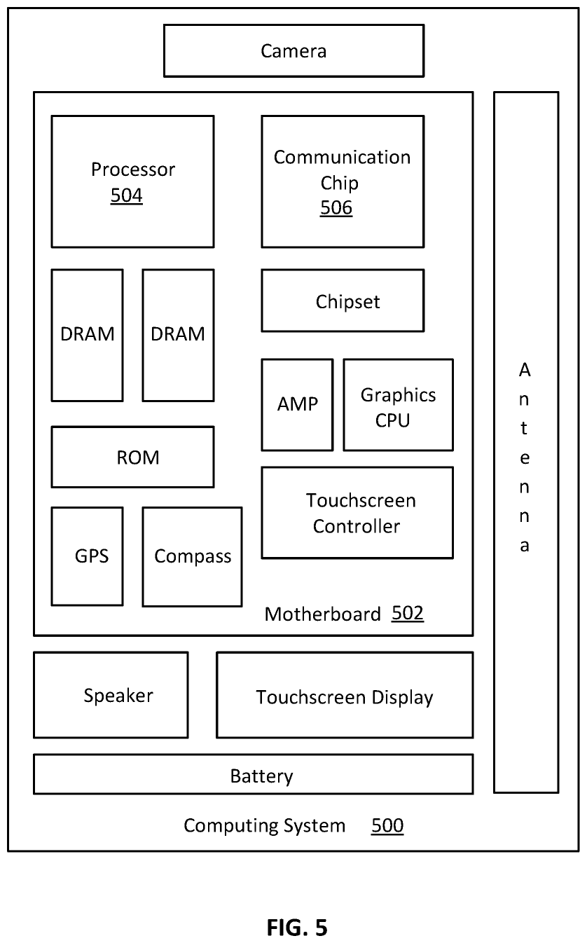

FIG. 5 is an example computing system implemented with one or more of the integrated circuit structures as disclosed herein, in accordance with some embodiments of the present disclosure. As can be seen, the computing system 500 houses a motherboard 502. The motherboard 502 may include a number of components, including, but not limited to, a processor 504 and at least one communication chip 506, each of which can be physically and electrically coupled to the motherboard 502, or otherwise integrated therein. As will be appreciated, the motherboard 502 may be, for example, any printed circuit board (PCB), whether a main board, a daughterboard mounted on a main board, or the only board of system 500, etc.

Depending on its applications, computing system 500 may include one or more other components that may or may not be physically and electrically coupled to the motherboard 502. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 500 may include one or more integrated circuit structures or devices configured in accordance with an example embodiment, such as a module including an integrated circuit on a substrate, the substrate having semiconductor devices and at least one via structure with a substrate tap. In some embodiments, multiple functions can be integrated into one or more chips (e.g., for instance, note that the communication chip 506 can be part of or otherwise integrated into the processor 504).

The communication chip 506 enables wireless communications for the transfer of data to and from the computing system 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing system 500 includes an integrated circuit die packaged within the processor 504. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 506 also may include an integrated circuit die packaged within the communication chip 506. In accordance with some such example embodiments, the integrated circuit die of the communication chip includes one or more semiconductor devices as variously described herein. As will be appreciated in light of this disclosure, note that multi-standard wireless capability may be integrated directly into the processor 504 (e.g., where functionality of any chips 506 is integrated into processor 504, rather than having separate communication chips). Further note that processor 504 may be a chip set having such wireless capability. In short, any number of processor 504 and/or communication chips 506 can be used. Likewise, any one chip or chip set can have multiple functions integrated therein.

In various implementations, the computing system 500 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 500 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is an integrated circuit that includes a semiconductor device having a semiconductor region extending in a first direction from a source or drain region and a gate structure extending in a second direction over the semiconductor region, a dielectric layer beneath the gate structure, and a via structure spaced from the semiconductor region in the second direction and extending in a third direction along an entire thickness of the gate structure and along an entire thickness of the dielectric layer. The via structure includes a conductive foot portion and a conductive arm portion extending from the conductive foot portion. The conductive foot portion is below a bottom surface of the gate structure and has a greater width in the second direction than a width in the second direction of any part of the conductive arm portion.

Example 2 includes the integrated circuit of Example 1, wherein the via structure comprises a conductive liner and a conductive fill on the conductive liner.

Example 3 includes the integrated circuit of Example 2, wherein the conductive liner comprises titanium and nitrogen.

Example 4 includes the integrated circuit of Example 2 or 3, wherein the conductive fill comprises tungsten, cobalt, ruthenium, or molybdenum.

Example 5 includes the integrated circuit of any one of Examples 1-4, wherein the conductive arm portion has a top end with a first width and a bottom end with a second width that is less than the first width, and wherein the bottom end is coupled directly to the conductive foot portion.

Example 6 includes the integrated circuit of any one of Examples 1-5, wherein at least a portion of the conductive foot portion of the via structure directly contacts the dielectric layer.

Example 7 includes the integrated circuit of any one of Examples 1-6, further comprising one or more dielectric layers on sidewalls of the conductive arm portion of the via structure, such that the one or more dielectric layers are between the conductive arm portion and the gate structure along the second direction.

Example 8 includes the integrated circuit of Example 7, wherein the one or more dielectric layers are between a portion of the conductive arm portion and the dielectric layer along the second direction.

Example 9 includes the integrated circuit of any one of Examples 1-8, wherein the semiconductor device is a first semiconductor device, the semiconductor region is a first semiconductor region, the source or drain region is a first source or drain region, and the gate structure is a first gate structure. The integrated circuit further includes a second semiconductor device having a second semiconductor region extending in the first direction from a second source or drain region and a second gate structure extending in the second direction over the second semiconductor region. The via structure is spaced from the second semiconductor region in the second direction such that the via structure is between the first semiconductor region and the second semiconductor region along the second direction.

Example 10 includes the integrated circuit of Example 9, wherein a first distance along the second direction between the conductive arm portion of the via structure and the first gate structure is substantially the same as a second distance along the second direction between the conductive arm portion of the via structure and the second gate structure. The first and second distances are on a same plane passing through the via structure.

Example 11 includes the integrated circuit of any one of Examples 1-10, wherein the width of the conductive foot portion is between about 15 nm and about 30 nm.

Example 12 includes the integrated circuit of any one of Examples 1-11, wherein a top surface of the conductive foot portion is below a top surface of the dielectric layer.

Example 13 includes the integrated circuit of any one of Examples 1-12, wherein the first direction is orthogonal to the second direction, and the third direction is orthogonal to the first and second directions.

Example 14 is a printed circuit board comprising the integrated circuit of any one of Examples 1-13.

Example 15 is an electronic device that includes a chip package having one or more dies. At least one of the one or more dies includes a semiconductor region extending in a first direction from a first source or drain region to a second source or drain region, a gate structure extending in a second direction over the semiconductor region, a dielectric layer beneath the gate structure, and a conductive via spaced from the semiconductor region in the second direction and extending in a third direction along an entire thickness of the gate structure and along an entire thickness of the dielectric layer. The conductive via includes a foot portion and an arm portion extending from the foot portion. The foot portion is below a bottom surface of the gate structure and has a greater width in the second direction than a width in the second direction of any part of the arm portion.

Example 16 includes the electronic device of Example 15, wherein the conductive via comprises a conductive liner and a conductive fill on the conductive liner.

Example 17 includes the electronic device of Example 16, wherein the conductive liner comprises titanium and nitrogen.

Example 18 includes the electronic device of Example 16 or 17, wherein the conductive fill comprises tungsten, cobalt, ruthenium, or molybdenum.

Example 19 includes the electronic device of any one of Examples 15-18, wherein the arm portion has a top end with a first width and a bottom end with a second width that is less than the first width, and wherein the bottom end is coupled directly to the foot portion.

Example 20 includes the electronic device of any one of Examples 15-19, wherein at least a portion of the foot portion of the conductive via directly contacts the dielectric layer.

Example 21 includes the electronic device of any one of Examples 15-20, wherein the at least one of the one or more dies further comprises one or more dielectric layers on sidewalls of the arm portion of the conductive via, such that the one or more dielectric layers are between the arm portion and the gate structure along the second direction.

Example 22 includes the electronic device of Example 21, wherein the one or more dielectric are between a portion of the arm portion and the dielectric layer along the second direction.

Example 23 includes the electronic device of any one of Examples 15-22, wherein the semiconductor region is a first semiconductor region, the source or drain region is a first source or drain region, and the gate structure is a first gate structure. The at least one of the one or more dies further includes a second semiconductor region extending in the first direction from a second source or drain region, and a second gate structure extending in the second direction over the second semiconductor region. The conductive via is spaced from the second semiconductor region in the second direction such that the conductive via is between the first semiconductor region and the second semiconductor region along the second direction.

Example 24 includes the electronic device of Example 23, wherein a first distance along the second direction between the arm portion of the conductive via and the first gate structure is substantially the same as a second distance along the second direction between the arm portion of the conductive via and the second gate structure. The first and second distances are on a same plane passing through the conductive via.

Example 25 includes the electronic device of any one of Examples 15-24, wherein the width of the foot portion is between about 15 nm and about 30 nm.

Example 26 includes the electronic device of any one of Examples 15-25, wherein a top surface of the foot portion is below a top surface of the dielectric layer.

Example 27 includes the electronic device of any one of Examples 15-26, wherein the first direction is orthogonal to the second direction, and the third direction is orthogonal to the first and second directions.

Example 28 includes the electronic device of any one of Examples 15-27, further comprising a printed circuit board, wherein the chip package is coupled to the printed circuit board.

Example 29 is a method of forming an integrated circuit. The method includes forming a fin comprising semiconductor material, the fin extending above a substrate and extending in a first direction; forming a dielectric layer adjacent to a subfin portion of the fin; forming source or drain regions at opposite ends of the fin; forming a gate structure on the dielectric layer and over the semiconductor material and extending in a second direction; forming a recess through an entire thickness of the gate structure and through an entire thickness of the dielectric layer; forming a sacrificial material within the recess such that a top surface of the sacrificial material is below a top surface of the dielectric layer; forming one or more dielectric layers along sidewalls of the recess and on a top surface of the sacrificial material; removing a portion of the one or more dielectric layers on the top surface of the sacrificial material; removing the sacrificial material from beneath the one or more dielectric layers to form a cavity beneath the one or more dielectric layers; forming one or more conductive materials on the one or more dielectric layers within the recess and within the cavity; and removing the substrate from a backside of the integrated circuit, wherein the removing exposes a bottom surface of the one or more conductive materials within the cavity.

Example 30 includes the method of Example 29, wherein the sacrificial material comprises a carbon hard mask (CHM).

Example 31 includes the method of Example 29 or 30, wherein forming the one or more dielectric layers comprises forming a first dielectric layer having silicon and nitrogen and forming a second dielectric layer on the first dielectric layer.

Example 32 includes the method of Example 31, wherein forming the first dielectric layer comprises forming the first dielectric layer at a temperature of less than 200° C.

Example 33 includes the method of Example 31 or 32, wherein forming the second dielectric layer comprises forming a low-k dielectric material.

Example 34 includes the method of any one of Examples 29-33, wherein forming the one or more conductive materials comprises forming a conductive liner and a conductive fill on the conductive liner.

Example 35 is an integrated circuit that includes a semiconductor device having a semiconductor region extending in a first direction from a source or drain region and a gate structure extending in a second direction over the semiconductor region, a dielectric layer beneath the gate structure, and a via structure spaced from the semiconductor region in the second direction and extending in a third direction along an entire thickness of the gate structure and along an entire thickness of the dielectric layer. The via structure includes a conductive structure passing through an axial center of the via structure and a dielectric structure along sidewalls of the conductive structure, such that the dielectric structure is between a portion of the conductive structure and the gate structure. The conductive structure extends below a bottom surface of the dielectric structure. The bottom surface of the dielectric structure is below a top surface of the dielectric layer.

Example 36 includes the integrated circuit of Example 35, wherein the conductive structure comprises a conductive liner and a conductive fill on the conductive liner.

Example 37 includes the integrated circuit of Example 36, wherein the conductive liner comprises titanium and nitrogen.

Example 38 includes the integrated circuit of Example 36 or 37, wherein the conductive fill comprises tungsten, cobalt, ruthenium, or molybdenum.

Example 39 includes the integrated circuit of any one of Examples 35-38, wherein the dielectric structure is also between a portion of the conductive structure and the dielectric layer.

Example 40 includes the integrated circuit of any one of Examples 35-39, wherein the dielectric structure comprises a first dielectric layer and a second dielectric layer on the first dielectric layer, wherein the first dielectric layer has a higher dielectric constant compared to the second dielectric layer.

Example 41 includes the integrated circuit of Example 40, wherein the first dielectric layer is between the second dielectric layer and the gate structure.

Example 42 includes the integrated circuit of any one of Examples 35-41, wherein the conductive structure has a first portion directly adjacent to the dielectric structure along the second direction and a second portion that extends below the bottom surface of the dielectric structure. The second portion has a greater width than any part of the first portion.

Example 43 includes the integrated circuit of Example 42, wherein the second portion of the conductive structure directly contacts the dielectric layer.

Example 44 includes the integrated circuit of Example 42 or 43, wherein the width of the second portion is between about 15 nm and about 30 nm.

Example 45 includes the integrated circuit of any one of Examples 35-44, wherein the semiconductor device is a first semiconductor device, the semiconductor region is a first semiconductor region, the source or drain region is a first source or drain region, and the gate structure is a first gate structure. The integrated circuit further includes a second semiconductor device having a second semiconductor region extending in the first direction from a second source or drain region and a second gate structure extending in the second direction over the second semiconductor region. The via structure is spaced from the second semiconductor region in the second direction such that the via structure is between the first semiconductor region and the second semiconductor region along the second direction.

Example 46 includes the integrated circuit of any one of Examples 35-45, wherein the first direction is orthogonal to the second direction, and the third direction is orthogonal to the first and second directions.

Example 47 is a printed circuit board comprising the integrated circuit of any one of Examples 35-46.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a semiconductor device having a semiconductor region extending in a first direction from a source or drain region, and a gate structure extending in a second direction over the semiconductor region;
a dielectric layer beneath the gate structure; and
a via structure spaced from the semiconductor region in the second direction and extending in a third direction along an entire thickness of the gate structure and along an entire thickness of the dielectric layer, wherein the via structure comprises a conductive foot portion and a conductive arm portion extending from the conductive foot portion, wherein the conductive foot portion is below a bottom surface of the gate structure and wherein the conductive foot portion has a greater width in the second direction than a width in the second direction of any part of the conductive arm portion.

2. The integrated circuit of claim 1, wherein the via structure comprises a conductive liner and a conductive fill on the conductive liner.

3. The integrated circuit of claim 1, wherein the conductive arm portion has a top end with a first width and a bottom end with a second width that is less than the first width, and wherein the bottom end is coupled directly to the conductive foot portion.

4. The integrated circuit of claim 1, wherein at least a portion of the conductive foot portion of the via structure directly contacts the dielectric layer.

5. The integrated circuit of claim 1, further comprising one or more dielectric layers on sidewalls of the conductive arm portion of the via structure, such that the one or more dielectric layers are between the conductive arm portion and the gate structure along the second direction.

6. The integrated circuit of claim 5, wherein the one or more dielectric layers are between a portion of the conductive arm portion and the dielectric layer along the second direction.

7. The integrated circuit of claim 1, wherein the semiconductor device is a first semiconductor device, the semiconductor region is a first semiconductor region, the source or drain region is a first source or drain region, and the gate structure is a first gate structure, the integrated circuit further comprising:
a second semiconductor device having a second semiconductor region extending in the first direction from a second source or drain region, and a second gate structure extending in the second direction over the second semiconductor region,
wherein the via structure is spaced from the second semiconductor region in the second direction such that the via structure is between the first semiconductor region and the second semiconductor region along the second direction.

8. The integrated circuit of claim 7, wherein a first distance along the second direction between the conductive arm portion of the via structure and the first gate structure is substantially the same as a second distance along the second direction between the conductive arm portion of the via structure and the second gate structure, the first and second distances being on a same plane passing through the via structure.

9. A printed circuit board comprising the integrated circuit of claim 1.

10. An electronic device, comprising:
a chip package comprising one or more dies, at least one of the one or more dies comprising
a semiconductor region extending in a first direction from a first source or drain region to a second source or drain region;
a gate structure extending in a second direction over the semiconductor region;
a dielectric layer beneath the gate structure; and
a conductive via spaced from the semiconductor region in the second direction and extending in a third direction along an entire thickness of the gate structure and along an entire thickness of the dielectric layer, wherein the conductive via comprises a foot portion and an arm portion extending from the foot portion, wherein the foot portion is below a bottom surface of the gate structure and wherein the foot portion has a greater width in the second direction than a width in the second direction of any part of the arm portion.

11. The electronic device of claim 10, wherein the arm portion has a top end with a first width and a bottom end with a second width that is less than the first width, and wherein the bottom end is coupled directly to the foot portion.

12. The electronic device of claim 10, wherein at least a portion of the foot portion of the conductive via directly contacts the dielectric layer.

13. The electronic device of claim 10, wherein the at least one of the one or more dies further comprises one or more dielectric layers on sidewalls of the arm portion of the conductive via, such that the one or more dielectric layers are between the arm portion and the gate structure along the second direction.

14. The electronic device of claim 10, further comprising a printed circuit board, wherein the chip package is coupled to the printed circuit board.

15. An integrated circuit comprising:
a semiconductor device having a semiconductor region extending in a first direction from a source or drain region, and a gate structure extending in a second direction over the semiconductor region;
a dielectric layer beneath the gate structure; and
a via structure spaced from the semiconductor region in the second direction and extending in a third direction along an entire thickness of the gate structure and along an entire thickness of the dielectric layer, the via structure comprising:
a conductive structure passing through an axial center of the via structure, and
a dielectric structure along sidewalls of the conductive structure, such that the dielectric structure is between a portion of the conductive structure and the gate structure,
wherein the conductive structure extends below a bottom surface of the dielectric structure, the bottom surface of the dielectric structure being below a top surface of the dielectric layer.

16. The integrated circuit of claim 15, wherein the dielectric structure is also between a portion of the conductive structure and the dielectric layer.

17. The integrated circuit of claim 15, wherein the dielectric structure comprises a first dielectric layer and a second dielectric layer on the first dielectric layer, wherein the first dielectric layer has a higher dielectric constant compared to the second dielectric layer.

18. The integrated circuit of claim 15, wherein the conductive structure has a first portion directly adjacent to the dielectric structure along the second direction and a second portion that extends below the bottom surface of the dielectric structure, wherein the second portion has a greater width than any part of the first portion.

19. The integrated circuit of claim 18, wherein the second portion of the conductive structure directly contacts the dielectric layer.

20. The integrated circuit of claim 15, wherein the semiconductor device is a first semiconductor device, the semiconductor region is a first semiconductor region, the source or drain region is a first source or drain region, and the gate structure is a first gate structure, the integrated circuit further comprising:
a second semiconductor device having a second semiconductor region extending in the first direction from a second source or drain region, and a second gate structure extending in the second direction over the second semiconductor region,
wherein the via structure is spaced from the second semiconductor region in the second direction such that the via structure is between the first semiconductor region and the second semiconductor region along the second direction.
